(19) United States
(12) Patent Application Publication
(10) Pub. No.: US 2021/0367031 A1
(43) Pub. Date: Nov. 25, 2021

(54) BJT Device Structure and Method for Making the Same

(71) Applicant: Shanghai Huali Integrated Circuit Corporation, Shanghai (CN)

(72) Inventors: Haitao Wang, Shanghai (CN); Xiaojun Zhou, Shanghai (CN)

(73) Assignee: Shanghai Huali Integrated Circuit Corporation, Shanghai (CN)

(21) Appl. No.: 16/937,845

(22) Filed: Jul. 24, 2020

(30) Foreign Application Priority Data
May 25, 2020 (CN) 202010446398.7

(51) Int. Cl. H01L 29/06; H01L 29/66; H01L 29/735

(52) U.S. Cl. CPC H01L 29/0649; H01L 29/735; H01L 29/6625

(57) ABSTRACT

The present application provides a BJT device structure and a method for making the same, the structure comprising an N+ region located on a P-well; a barrier layer structure located on the N+ region, the barrier layer structure being a frame structure surrounding the periphery of the N+ region, wherein a region in the barrier layer structure is an emitter region, a plurality of mutually spaced STI regions are provided on the N+ region of the emitter region; a base region located at the periphery of the emitter region; and a collector region located at the periphery of the base region. The STI region of the emitter region of the BJT device structure of the present application is a discontinuous structure, which can significantly reduce a recombination current of the emitter region and the base region, thereby effectively increasing the amplification factor of the BJT device.

### CROSS-REFERENCES TO RELATED APPLICATIONS

This application claims priority to Chinese Patent Application No. CN202010446398.7, filed on May 25, 2020, and entitled “BJT DEVICE STRUCTURE AND METHOD FOR MAKING THE SAME”, the disclosure of which is incorporated herein by reference in entirety.

### TECHNICAL FIELD

The present application relates to the field of semiconductor manufacturing, in particular to a BJT device structure and a method for making the same.

### BACKGROUND

A bipolar junction transistor (BJT), such as a BJT device of an NPN structure, in the general logic circuit is parasitically generated on the basis of the existing ion implantation conditions and cannot be adjusted independently, thereby presenting a relatively small beta (amplification factor), in particular, as the emitter area increases (other conditions remain unchanged), the current gain decreases significantly. Taking PNP as an example, the emitter thereof is located in the middle of the entire transistor, and the edge is surrounded by a silicide block to reduce recombination at the junction of the diffusion region and the STI region, thereby improving the performance of the BJT. Currently, a typical manufacturing process of the CMOS in the integration process is as follows: (1) an active region of the device is formed by means of a shallow trench isolation process; (2) P-type and N-type wells are formed by means of ion implantation; (3) a gate oxide is grown, and a gate is formed; (4) a gate sidewall is formed; (5) an LDD region is formed by means of ion implantation; (6) a gate main sidewall is formed; (7) an emitter, a base, and a collector are formed by means of ion implantation; (8) a SAB film is deposited; (9) a metal silicide-metal electrode is formed; and (10) a backend metal layer interconnection is formed, and a WAT test is performed. The manufacturing of the BJT mainly involves processes (1), (2), and (7)-(10).

However, the amplification factor of the BJT device structure in the prior art is generally small, so it is necessary to propose a new structure and method to effectively increase the amplification factor of the BJT device.

### BRIEF SUMMARY

In view of the defects of the prior art described above, an objective of the present application is to provide a BJT device structure and a method for making the same, to solve the problem of a small amplification factor of a BJT device in the prior art.

In order to achieve the objective described above and other related objective, the present application provides a BJT device structure, the structure comprising at least:

a P-well; an N+ region located on the P-well; a barrier layer structure located on the N+ region, the barrier layer structure being a frame structure surrounding the periphery of the N+ region, wherein a region in the barrier layer structure is an emitter region of the BJT device, a plurality of mutually spaced STI regions are provided on the N+ region of the emitter region, and an upper surface of the P-well is above the bottom of the STI region;

a base region located at the periphery of the emitter region; and a collector region located at the periphery of the base region.

In some examples, cross-sectional shapes of the plurality of mutually spaced STI regions are a plurality of mutually spaced strip structures, and the plurality of strip structures are evenly spaced in the barrier layer structure.

In some examples, the base region located at the periphery of the emitter region is isolated from the emitter region by an STI region and is led out from the P-well, and a P+ region is provided on the P-well for leading-out.

In some examples, a metal electrode constituting a base of the BJT device structure is provided on the P+ region.

In some examples, the collector region consists of an N-well located at the periphery of the P-well and an N+ region on the N-well, and the collector region is isolated from the base region by an STI region.

In some examples, a metal electrode constituting a collector of the BJT device structure is provided on the N+ region constituting the collector region.

In some examples, the cross-sectional dimension of the emitter region is 2 μm*2 μm.

The present application further provides a method for manufacturing a BJT device structure, the method comprising at least the following steps:

step 1: synchronously manufacturing STI regions for isolating an emitter region, a base region, and a collector region and a plurality of mutually spaced STI regions located in a region of the emitter region to be formed;

step 2: performing ion implantation in regions of the emitter region and the base region to be formed, to form a P-well, and performing ion implantation in a region of the collector region to be formed, to form an N-well, wherein upper surfaces of the P-well and the N-well are above the bottom of the STI region;

step 3: separately performing N-type ion heavy doping on the P-well of the emitter region to be formed and on the N-well of the collector region to be formed, to form an N+ region, and performing P-type ion heavy doping on the P-well of the base region to be formed, to form a P+ region;

step 4: forming a barrier layer structure on the N+ region constituting the emitter region, the barrier layer structure being a frame structure surrounding the periphery of the N+ region of the emitter region; and

step 5: forming metal electrodes on the P+ region of the base region and the N+ region of the collector region, respectively.

In some examples, the method of forming a barrier layer structure on the N+ region constituting the emitter region in step 4 comprises steps of: (1) depositing a layer of metal silicide on the N+ region and the P+ region; and (2) forming the frame structure of the metal silicide that surrounds the periphery of the N+ region on the N+ region constituting the emitter region by means of photolithography and etching processes.

In some examples, the method further comprises step 6: performing a WAT test on the BJT device structure to extract a current gain thereof.

As described above, the BJT device structure and the method for making the same of the present application have the following beneficial effects: the STI region of the emitter region of the BJT device structure of the present application is a discontinuous structure, which can significantly reduce a recombination current of the emitter region and the base region, thereby effectively increasing the amplification factor of the BJT device.

### BRIEF DESCRIPTION OF THE DRAWINGS

FIG. 1 illustrates a schematic diagram of a sectional structure of a BJT device of the present application.

FIG. 2 illustrates a schematic diagram of a cross-sectional structure of the BJT device of the present application.

FIG. 3 illustrates a curve of a relationship between an amplification factor of the BJT device of the present application and an electrical parameter Vbe.

FIG. 4 illustrates a curve of a relationship between a base region current of the BJT device of the present application and the electrical parameter Vbe.

FIG. 5a illustrates a TCAD simulation diagram of the electron current density of a BJT device in the prior art.

FIG. 5b illustrates a TCAD simulation diagram of the electron current density of the BJT device of the present application.

### DETAILED DESCRIPTION OF THE DISCLOSURE

The embodiments of the present application are described below by means of specific examples, and those skilled in the art can easily understand other advantages and effects of the present application from the contents disclosed in the description. The present application can also be implemented or applied via other different specific embodiments. Various details in the description can also be modified or changed based on different viewpoints and applications, without departing from the spirit of the present application.

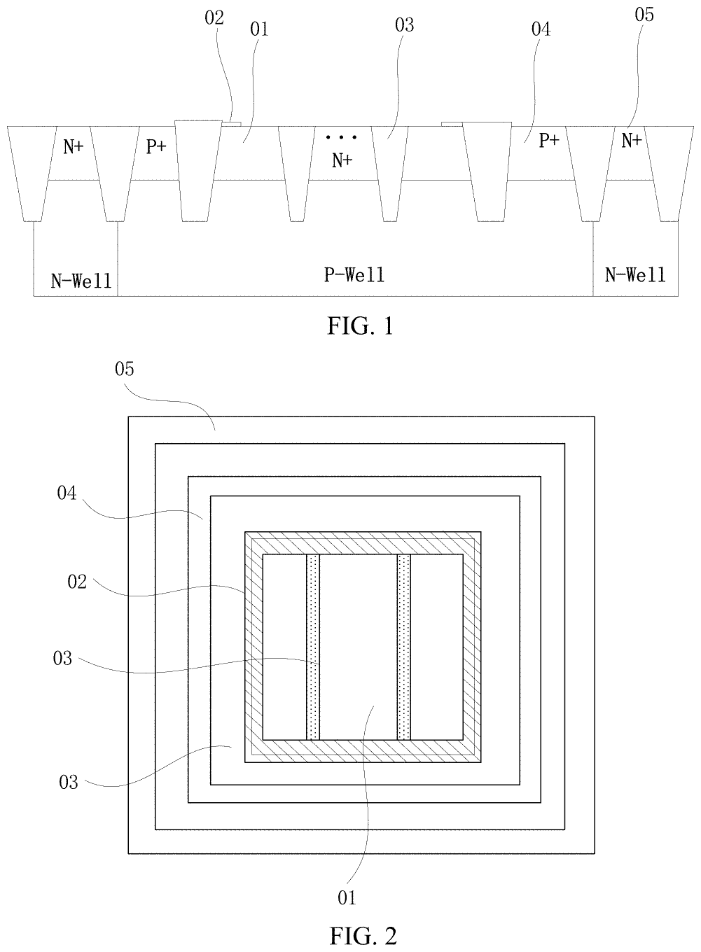

Referring to FIGS. 1-5b, it should be noted that the drawings provided in this embodiment illustrate the basic concept of the present application in a schematic manner only, and only the components related to the present application are shown in the drawings, without being drawn according to the number, shape, and size of the components in actual implementation. The type, number, and scale of each component can be changed at random during the actual implementation, and the component layout type may be more complicated.

The present application provides a BJT device structure, referring to FIG. 1, which illustrates a schematic diagram of a sectional structure of the BJT device of the present application, the structure includes at least: a P-well; an N+ region 01 located on the P-well; and a barrier layer structure 02 located on the N+ region 01, the barrier layer structure 02 being a frame structure surrounding the periphery of the N+ region. The barrier layer structure is as shown in FIG. 2, which illustrates a schematic diagram of a cross-sectional structure of the BJT device of the present application. A region in the barrier layer structure 02 is an emitter region of the BJT device, and the emitter region consists of the P-well and the N+ region on the P-well. A plurality of mutually spaced STI regions 03 are provided on the N+ region 01 of the emitter region, and an upper surface of the P-well is above the bottom of the STI region. Referring to FIG. 2, the STI region located in the emitter region is located in the barrier layer structure, and the plurality of STI regions 03 are discontinuous structures located in the emitter region. In this embodiment, the discontinuous structures are mutually spaced in the frame structure. The frame structure of the barrier layer structure surrounds the periphery of the N+ region of the emitter region.

Referring to FIG. 2, in another example of the present application, cross-sectional shapes of the plurality of mutually spaced STI regions 03 are a plurality of mutually spaced strip structures, and the plurality of strip structures are evenly spaced in the barrier layer structure.

The BJT device structure of the present application further includes a base region located at the periphery of the emitter region and a collector region located at the periphery of the base region. In another example of the present application, referring to FIG. 1, the base region located at the periphery of the emitter region is isolated from the emitter region by an STI region and is led out from the P-well, and a P+ region is provided on the P-well for leading-out. Referring to FIG. 2, it can be seen that the base region located at the periphery of the emitter region consists of the P-well and the P+ region 04 located on the P-well. Referring to FIG. 1, the P-well constituting the base region is led out from the P-well constituting the emitter region. The N+ region 01 of the emitter region and the P+ region 04 of the base region are isolated from each other by the STI region.

In another example of the present application, a metal electrode constituting a base of the BJT device structure is provided on the P+ region. The metal electrode on the P+ region 04 is not shown in FIGS. 1 and 2 of the present application.

In another example of the present application, referring to FIG. 2, the collector region consists of an N-well located at the periphery of the P-well and an N+ region 05 on the N-well, and the collector region is isolated from the base region by an STI region. Referring to FIG. 1, the collector region is located at the periphery of the base region, the N-well is provided at the periphery of the P-well, the N+ region 05 is provided on the N-well, the N-well and the N+ region located thereon constitute the collector region of the BJT device structure, and the collector region and the base region are isolated from each other by the STI region.

In another example of the present application, the cross-sectional dimension of the emitter region is 2 μm*2 μm. The type of the BJT device of the present application is an NPN type.

The present application further provides a method for manufacturing the BJT device structure, and the method includes at least the following steps:

Step 1: STI regions for isolating an emitter region, a base region, and a collector region and a plurality of mutually spaced STI regions located in a region of the emitter region to be formed are synchronously manufactured. Referring to FIG. 1, in step 1, a shallow trench isolation region is formed by means of etching on a substrate and then filled with silicon oxide to form an STI region, thereby forming an active region. The emitter region, the base region, and the collector region of the BJT device are manufactured in the active region, the emitter region is isolated from the base region by an STI region, and the base region is isolated from the collector region by an STI region. In this step, the plurality of mutually spaced STI regions 03 are first manufactured in a region of the emitter region to be formed, and the plurality of mutually spaced STI regions 03 in the emitter region, the STI region used to isolate the emitter region and the base region, and the STI region used to isolate the base region and the collector region are formed synchronously. Referring to FIG. 2, it can be seen that cross-sectional (FIG. 2 is a top view of FIG. 1) shapes of the plurality of mutually spaced STI regions in the emitter region are evenly spaced strip structures.

Step 2: Ion implantation is performed in regions of the emitter region and the base region to be formed, to form a P-well (P-well in FIG. 1), and ion implantation is performed in a region of the collector region to be formed, to form an N-well (N-well in FIG. 1), wherein upper surfaces of the P-well and the N-well are above the bottom of the STI region.

Step 3: N-type ion heavy doping is separately performed on the P-well of the emitter region to be formed and on the N-well of the collector region to be formed, to form an N+ region, and P-type ion heavy doping is performed on the P-well of the base region to be formed, to form a P+ region. In step 3, the N-type ion heavy doping is performed on the P-well of the emitter region to be formed, to form the N+ region 01 constituting the emitter region; the N-type ion heavy doping is performed on the N-well of the collector region to be formed, to form the N+ region 05 constituting the collector region; and the P-type ion heavy doping is performed on the P-well of the base region to be formed, to form the P+ region 04 constituting the base region.

Step 4: A barrier layer structure is formed on the N+ region constituting the emitter region. Referring to FIG. 2, it can be seen that the barrier layer structure 02 is a frame structure surrounding the periphery of the N+ region of the emitter region. In another example, the method of forming a barrier layer structure on the N+ region constituting the emitter region in step 4 includes steps of: (1) a layer of metal silicide is deposited on the N+ region and the P+ region; and (2) the frame structure of the metal silicide that surrounds the periphery of the N+ region is formed on the N+ region constituting the emitter region by means of photolithography and etching processes. The formation of the barrier layer structure includes transferring a pattern of the barrier layer structure to a photoresistor on the N+ region on the P-well after one-time exposure using a photomask corresponding to the barrier layer structure. Thereafter, remaining metal silicide is removed by means of development and etching, to obtain the frame structure.

Step 5: Metal electrodes are formed on the P+ region of the base region and the N+ region of the collector region, respectively.

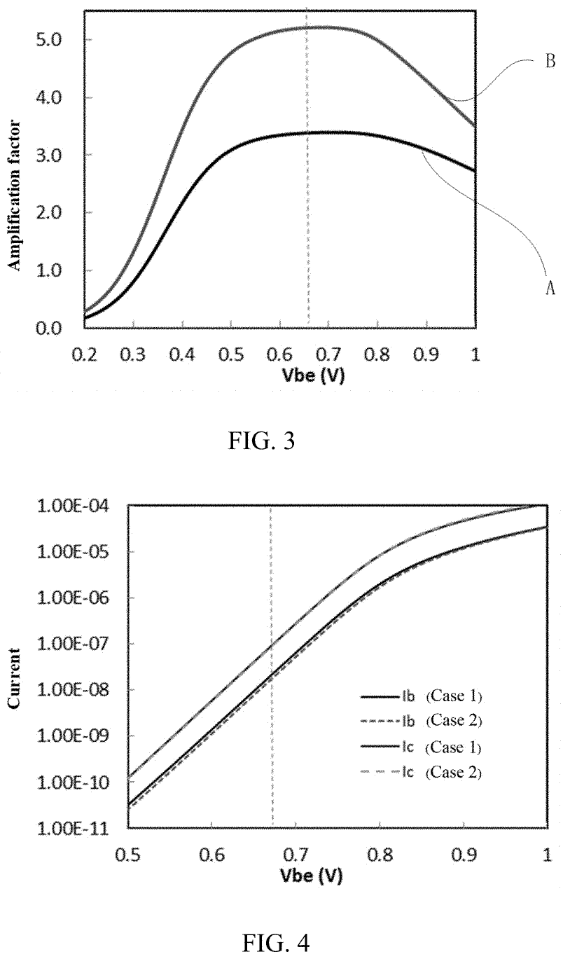

The method further includes step 6: a WAT test is performed on the BJT device structure to extract a current gain thereof. Referring to FIGS. 3 and 4, FIG. 3 illustrates curves of relationships between amplification factors of a BJT device in the prior art and the BJT device of the present application and an electrical parameter Vbe, wherein curve A represents the relationship between the amplification factor of the BJT device in the prior art and the electrical parameter Vbe, and curve B represents the relationship between the amplification factor of the BJT device of the present application and the electrical parameter Vbe. It can be seen that the BJT device structure of the present application increases the amplification factor by 54%.

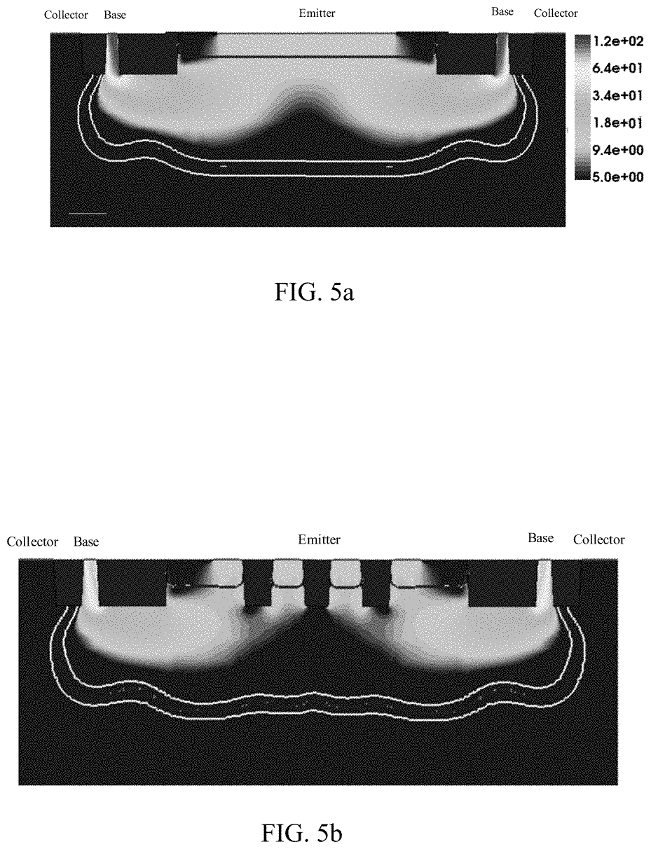

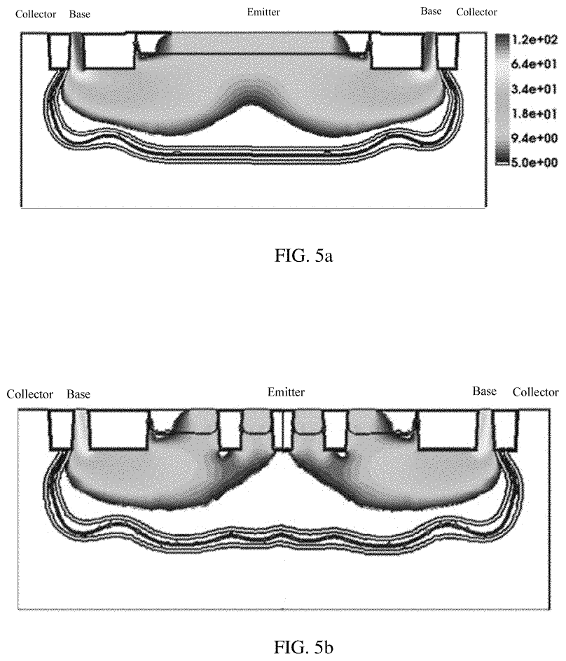

FIG. 4 illustrates curves of relationships between currents of the BJT device in the prior art and the BJT device of the present application and the electrical parameter Vbe, wherein ib (case 1) and is (case 1) are the curves of the relationship between the current of the BJT device in the prior art and the electrical parameter Vbe, and ib (case 2) and is (case 2) are the curves of the relationship between the current of the BJT device of the present application and the electrical parameter Vbe. It can be seen from the relationship curves that the current of Ib is decreased significantly. Regarding the NPN type, Ib is an electron current flowing from the base region to the emitter region, and the structure of the present application can significantly reduce this current. Referring to FIG. 5b, TCAD simulation results show the BJT structure proposed herein. FIG. 5a illustrates a TCAD simulation diagram of the electron current density of the BJT device in the prior art, and FIG. 5b illustrates a TCAD simulation diagram of the electron current density of the BJT device of the present application. It can be seen from comparison that, in the BJT device of the present application, an electron current flowing into the base region is significantly reduced, thereby effectively improving the beta. In the BJT device of the present application, a discontinuous STI region is provided on the N+ region of the emitter region, thereby significantly reducing the recombination current 1b between the base and the emitter. Referring to FIG. 5b, it can be seen that the hole current density of the new structure proposed by the present application is much less than that of the existing structure, thereby increasing the amplification factor.

In conclusion, the BJT device structure and the method for making the same of the present application have the following beneficial effects: the STI region of the emitter region of the BJT device structure of the present application is a discontinuous structure, which can significantly reduce a recombination current of the emitter region and the base region, thereby effectively increasing the amplification factor of the BJT device. Therefore, the present application effectively overcomes various defects in the prior art and has high industrial utilization value.

The embodiments described above illustrate the principle and effect of the present application and are not intended to limit the present application. Any person familiar with this technology can modify or change the above embodiments, without departing from the spirit and scope of the present application. Therefore, all equivalent modifications or changes made by those with ordinary knowledge in the technical field without departing from the spirit and technical idea disclosed by the present application shall fall with claims of the present application.

1. A bipolar junction transistor (BJT) device structure, wherein the BJT device structure comprises at least:
a P-well; an N+ region located on the P-well; a barrier layer structure located on the N+ region, the barrier layer structure being a frame structure surrounding a periphery of the N+ region, wherein a region in the barrier layer structure is an emitter region of the BJT device, a plurality of mutually spaced STI regions are provided on the N+ region of the emitter region, and an upper surface of the P-well is above a bottom of the STI regions;
a base region located at a periphery of the emitter region; and a collector region located at a periphery of the base region.

2. The BJT device structure according to claim 1, wherein cross-sectional shapes of the plurality of mutually spaced STI regions are a plurality of mutually spaced strip structures, and the plurality of mutually spaced strip structures are evenly spaced in the barrier layer structure.

3. The BJT device structure according to claim 1, wherein the base region located at the periphery of the emitter region is isolated from the emitter region by an STI region and is led out from the P-well, and a P+ region is provided on the P-well for leading-out.

4. The BJT device structure according to claim 3, wherein a metal electrode constituting a base of the BJT device structure is provided on the P+ region.

5. The BJT device structure according to claim 4, wherein the collector region consists of an N-well located at a periphery of the P-well and an N+ region on the N-well, and the collector region is isolated from the base region by an STI region.

6. The BJT device structure according to claim 5, wherein a metal electrode constituting a collector of the BJT device structure is provided on the N+ region constituting the collector region.

7. The BJT device structure according to claim 1, wherein a cross-sectional dimension of the emitter region is 2 μm*2 μm.

8. A method for manufacturing the BJT device structure according to claim 1, wherein the method comprises:
step 1: synchronously manufacturing STI regions for isolating the emitter region, the base region, and the collector region and a plurality of mutually spaced STI regions located in a region of the emitter region to be formed;
step 2: performing ion implantation in regions of the emitter region and the base region to be formed, to form the P-well, and performing ion implantation in a region of the collector region to be formed, to form an N-well, wherein upper surfaces of the P-well and the N-well are above the bottom of the STI region;
step 3: separately performing N-type ion heavy doping on the P-well of the emitter region to be formed and on the N-well of the collector region to be formed, to form an N+ region, and performing P-type ion heavy doping on the P-well of the base region to be formed, to form a P+ region;
step 4: forming a barrier layer structure on the N+ region constituting the emitter region, the barrier layer structure being a frame structure surrounding the periphery of the N+ region of the emitter region; and
step 5: forming metal electrodes on the P+ region of the base region and the N+ region of the collector region, respectively.

9. The method for manufacturing the BJT device structure according to claim 8, wherein the forming the barrier layer structure on the N+ region constituting the emitter region comprises: (1) depositing a layer of metal silicide on the N+ region and the P+ region; and (2) forming the frame structure of the metal silicide that surrounds the periphery of the N+ region on the N+ region constituting the emitter region by means of photolithography and etching processes.

10. The method for manufacturing the BJT device structure according to claim 8, wherein the method further comprises step 6: performing a WAT test on the BJT device structure to extract a current gain thereof.
